(19) United States
(12) Patent Application Publication
(10) Pub. No.: US 2021/0375811 A1
(43) Pub. Date: Dec. 2, 2021

(54) PIN-GRID-ARRAY-TYPE SEMICONDUCTOR PACKAGE

(71) Applicant: MK ELECTRON CO., LTD., Yongin-si (KR)

(72) Inventors: Jae Yeol SON, Cheoin-gu (KR); Jeong Tak Moon, Jangan-gu (KR); Jae Hun Song, Suji-gu (KR); Young Woo Lee, Cheoin-go (KR); Seul Gi Lee, Cheoin-gu (KR); Min Su Park, Giheung-gu (KR); Hui Joong Kim, Jongno-gu (KR)

(73) Assignee: MK ELECTRON CO., LTD., Yongin-si (KR)

(21) Appl. No.: 17/323,722

(22) Filed: May 18, 2021

(30) Foreign Application Priority Data
May 29, 2020 (KR) 10-2020-0065396

(51) Int. Cl. H01L 23/00; H01L 23/498; H01L 23/532; H01L 21/50

(52) U.S. Cl. CPC H01L 24/14; H01L 23/49816; H01L 2021/60022; H01L 21/50; H01L 23/53242

(57) ABSTRACT

A semiconductor package of a pin-grid-array type includes a bump pad on a first substrate, a metal socket on a second substrate, a core material for reverse reflow on the bump pad, and solder paste or a solder bump forming a solder layer on the core material for reverse reflow. The solder paste or the solder bump is in contact with the bump pad. The core material for reverse reflow and the solder paste or the solder bump bonded to the core material for reverse reflow are used as a pin and detachably attached to the metal socket. The core material for reverse reflow includes a core, a first metal layer directly coated on the core, and a second metal layer directly coated on the first metal layer.

### CROSS-REFERENCE TO RELATED APPLICATION

This application is based on and claims priority under 35 U.S.C. § 119 to Korean Patent Application No. 10-2020-0065396, filed on May 29, 2020, in the Korean Intellectual Property Office, the disclosure of which is incorporated by reference herein in its entirety.

### BACKGROUND

### 1. Field

One or more embodiments relate to a semiconductor package and a method of manufacturing the semiconductor package, and more particularly, to a pin-grid-array-type semiconductor package using a core material for reverse reflow as a pin and a method of manufacturing the semiconductor package.

### 2. Description of the Related Art

A tin (Sn)-lead (Pb)-based alloy product is mainly used as solder used for electronic products. In particular, lead acts as a component that determines the wetting, strength, and mechanical properties of an alloy. By including lead in an alloy, a melting point of the alloy may be lowered to about 183° C., thereby preventing thermal damage caused by a soldering process in a semiconductor process. Moreover, as regulations regarding environmental problems caused by lead become strict, a ternary lead-free solder alloy including tin (Sn), silver (Ag), and copper (Cu) has been proposed. To enable high-density mounting of a semiconductor package, after a metal or nonmetal core material is plated with nickel (Ni), plating balls including a binary plating layer including tin and silver or a ternary plating layer including tin, silver, and copper are being used to transmit an electric signal to the semiconductor package. Various studies are being conducted on methods of applying such plating balls.

### SUMMARY

One or more embodiments include a pin-grid-array-type semiconductor package having a high precision and an excellent bonding strength by using a core material for reverse reflow as a pin.

One or more embodiments include a method of manufacturing a pin-grid-array-type semiconductor package having a high precision and an excellent bonding strength by using a core material for reverse reflow as a pin.

One or more embodiments include an electronic system including a pin-grid-array-type semiconductor package having a high precision and an excellent bonding strength by using a core material for reverse reflow as a pin.

Aspects of the inventive concept should not be limited by the above description, and other unmentioned aspects will be clearly understood by one of ordinary skill in the art from example embodiments described herein.

Additional aspects will be set forth in part in the description which follows and, in part, will be apparent from the description, or may be learned by practice of the presented embodiments of the disclosure.

According to one or more embodiments, a semiconductor package of a pin-grid-array type includes a bump pad on a first substrate, a metal socket on a second substrate, a core material for reverse reflow on the bump pad, and solder paste or a solder bump forming a solder layer on the core material for reverse reflow. The solder paste or the solder bump is in contact with the bump pad. The core material for reverse reflow and the solder paste or the solder bump bonded to the core material for reverse reflow are used as a pin and detachably attached to the metal socket. A first diameter of the bump pad is less than or equal to a second diameter of the core material for reverse reflow. The core material for reverse reflow includes a core, a first metal layer directly coated on the core, and a second metal layer directly coated on the first metal layer. The first metal layer includes nickel (Ni) or cobalt (Co). The second metal layer includes gold (Au) or platinum (Pt).

According to one or more embodiments, a method of manufacturing a semiconductor package of a pin-grid-array type includes providing a first substrate on which a bump pad is arranged. A second substrate on which a metal socket is arranged is provided. Solder paste or a solder bump is mounted on the bump pad. A core material for reverse reflow is arranged on the solder paste or the solder bump. The solder paste or the solder bump is reflowed to form a solder layer on at least a side surface of the core material for reverse reflow. The core material for reverse reflow and the solder paste or the solder bump bonded to the core material for reverse reflow are used as a pin, and the pin is coupled to the metal socket. The core material for reverse reflow includes a core, a first metal layer directly coated on the core, and a second metal layer directly coated on the first metal layer. The first metal layer includes nickel or cobalt. The second metal layer includes gold or platinum.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view of a core material for reverse reflow, according to an embodiment;

FIG. 2 is a cross-sectional view of a pin-grid-array-type semiconductor package, according to an embodiment;

FIG. 3 is a partial enlarged view of region CC of FIG. 2, according to an embodiment;

FIG. 4 is a partial enlarged view of region CC of FIG. 2, according to an embodiment;

FIG. 5 is a graph showing the strength of a pin in a semiconductor package according to an embodiment;

FIG. 6 is a flowchart of a method of manufacturing a semiconductor package, according to an embodiment;

FIGS. 7A to 7E are cross-sectional views of a process sequence a method of manufacturing a semiconductor package, according to an embodiment;

FIG. 8 is a plan view of a memory module including a semiconductor package, according to an embodiment;

FIG. 9 is a schematic view of a memory card including a semiconductor package, according to an embodiment;

FIG. 10 is a block diagram of a memory device including a semiconductor package, according to an embodiment;

FIG. 11 is a block diagram of an electronic system including a semiconductor package, according to an embodiment; and

FIG. 12 is a block diagram of a network for a server system including a semiconductor package, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Embodiments will now be described in further detail with reference to the accompanying drawings. Embodiments may, however, be embodied in many different forms and should not be construed as limited to the embodiments set forth herein.

Like numbers refer to like elements throughout. Furthermore, various elements and regions are approximately illustrated in the drawings. Accordingly, the scope of the inventive concept is not limited by relative sizes or intervals in the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless explicitly so defined herein.

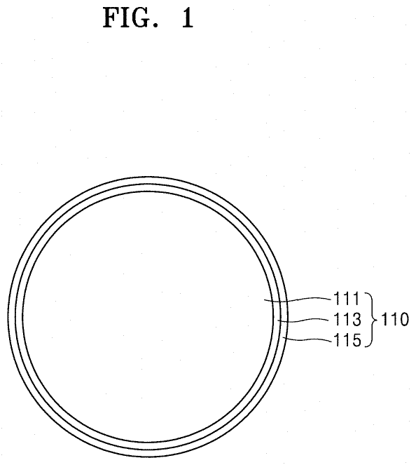

FIG. 1 is a cross-sectional view of a core material 110 for reverse reflow, according to an embodiment.

Referring to FIG. 1, the core material 110 for reverse reflow may include a core 111, a first metal layer 113 coated on the core 111, and a second metal layer 115 coated on the first metal layer 113.

The core 111 may include a typical metal material, an organic material, an organic/organic composite material, or an organic/inorganic composite material.

The core 111 including the organic material may be, for example, the core 111 including a plastic material. The core 111 including the plastic material may include a plastic core including a thermosetting resin; a plastic core including a thermoplastic resin; and an elastic core. The thermosetting resin may include epoxies, melamine-formaldehydes, benzoguanamine-formaldehydes, divinylbenzene, divinyl ether, polydiacrylate, and alkylene bisacrylamide. The thermoplastic resin may include polyvinyl chloride, polyethylene, polystyrene, nylon, and polyacetal. The elastic core may include natural rubber and synthetic rubber. Furthermore, the core 111 may include a plastic core including a resin mixture of a thermosetting resin and a thermoplastic resin.

Moreover, the core 111 including the plastic material may be formed using a polymer synthesis method. In some embodiments, the core 111 including the plastic material may be formed to have a diameter of about 21 μto about 500 μm by using a synthesis method, such as a suspension method, an emulsification method, and a dispersion polymerization method.

The core 111 including the metal material may include, for example, pure copper (Cu), nickel (Ni), aluminum (Al), or an alloy thereof, without being limited thereto.

Although the core 111 having a spherical shape is illustrated, the core 111 may have various shapes, such as a cylindrical shape, a square pillar shape, a polygonal pillar shape, a conical shape, and a pyramid shape.

The first metal layer 113 may be provided on the core 111. The first metal layer 113 may be formed directly on the core 111 or formed on the core 111 by interposing another material layer therebetween.

Although components of the first metal layer 113 are not specifically limited, a metal, such as gold (Au), silver (Ag), nickel (Ni), zinc (Zn), tin (Sn), aluminum (Al), chromium (Cr), cobalt (Co), and antimony (Sb), may be used. The components of the first metal layer 113 may be used alone or in combination of at least two thereof. The first metal layer 113 may be formed using a method, such as a plating process, a physical vapor deposition (PVD) process, and a chemical vapor deposition (CVD) process. In particular, when the first metal layer 113 is formed using a plating process, the first metal layer 113 may be formed by an electroplating process using nickel (Ni) or an electroless process.

The first metal layer 113 may be formed using a brightener to improve a roughness of a surface of the first metal layer 113. That is, the first metal layer 113 having a relatively smooth surface may be obtained by using the brightener. The brightener may include, for example, an oxygen-containing organic compound (e.g., a polyether-based compound); a nitrogen-containing organic compound (e.g., a tertiary amine compound and a quaternary ammonium compound); and/or a sulfur-containing organic compound having a sulfonate group, without being limited thereto.

The first metal layer 113 may have a thickness of about 1 μm to about 5 μm. The first metal layer 113 may be reacted with tin (Sn)-based solder paste to form, for example, an intermetallic compound, such as

(Ni,Cu)₃Sn₄, (Cu,Ni)₆Sn₅, and Ni₃Sn₄.

The second metal layer 115 may be formed on a surface of the first metal layer 113. The second metal layer 115 may have a thickness of about 0.01 μm to about 0.3 μm. When the second metal layer 111 has an excessively small thickness, a solder layer may not be formed over an entire surface of the core material 110 for reverse reflow when the core material 110 for reverse reflow is subsequently used for a reflow process. When the second metal layer 115 has an excessively large thickness, economical efficiency may be adversely affected, and the second metal layer 115 may react with tin-based solder during a subsequent reflow process to form an intermetallic compound (e.g., AuSn₄) having a low strength.

The second metal layer 115 may include, for example, gold (Au), platinum (Pt), or an alloy thereof. The second metal layer 115 may be easily mixed with the solder layer due to heating. In addition, because the second metal layer 115 includes a metal having an oxidation resistance, the second metal layer 115 may suppress the oxidation of a surface of the core material 110 for reverse reflow.

The second metal layer 115 may be formed using a method, such as an electroplating process, an electroless process, a PVD process, and a CVD process, without being limited thereto.

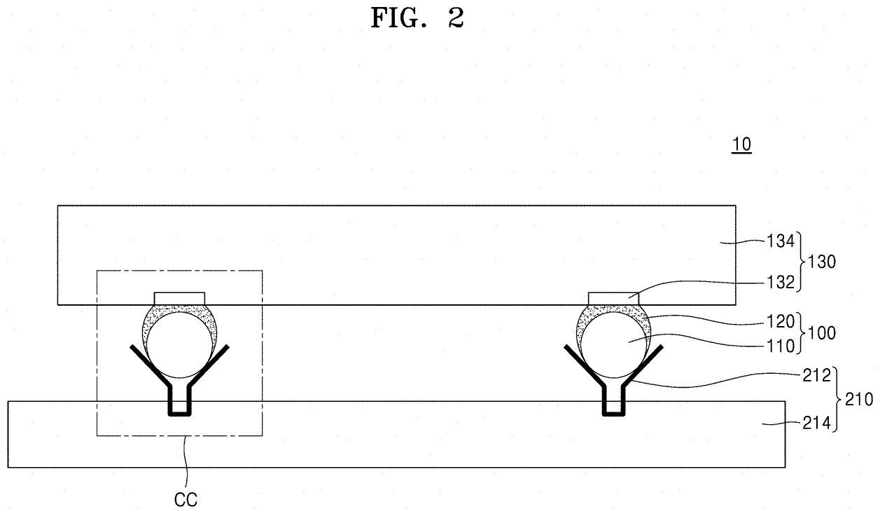

The core material 110 for reverse reflow may not be used solely as a pin (refer to 100 in FIG. 2) but form a portion of the pin 100 for a pin grid array method by undergoing a reflow process together with solder paste (refer to 120 in FIG. 2), as will be described in detail below.

FIG. 2 is a cross-sectional view of a semiconductor package 10 of a pin-grid-array type, according to an embodiment.

Referring to FIG. 2, the semiconductor package 10 may include a core material 110 for reverse reflow and solder paste 120, which serve as a pin 100.

In the core material 110 for reverse reflow, for example, a core 111 may have a diameter of about 21 μm to about 500 μm, a first metal layer 113 may have a thickness of about 1 μm to about 5 μm, and a second metal layer 115 may have a thickness of about 0.01 μm to about 0.3 μm. However, the diameter of the core material 110 for reverse reflow is not limited thereto. Because the core material 110 for reverse reflow has been described above in detail with reference to FIG. 1, an additional description thereof is omitted.

The solder paste 120 may refer to a solder layer surrounding the core material 110 for reverse reflow. In addition, the solder paste 120 may be used herein as a concept including a solder bump, such as a solder ball. Here, solder paste or a solder bump may be collectively referred to as the solder paste 120 for brevity.

Conductive metal powder used for the solder paste 120 may include, for example, at least one selected from tin (Sn), gold (Au), silver (Ag), platinum (Pt), copper (Cu), bismuth (Bi), palladium (Pd), chromium (Cr), calcium (Ca), nickel (Ni), germanium (Ge), zinc (Zn), manganese (Mn), cobalt (Co), tungsten (W), antimony (Sb), lead (Pb), and an arbitrary alloy thereof.

In some embodiments, the solder paste 120 may include a lead-containing solder alloy (e.g., a Sn—Pb-based alloy or a Sn—Pb—Ag-based alloy) or a lead-free solder alloy (e.g., a Sn—Ag-based alloy, a Sn—Bi-based alloy, a Sn—Zn-based alloy, a Sn—Sb-based alloy, or a Sn—Ag—Cu-alloy). The solder paste 120 may include at least 50%, at least 60%, or at least 90% by weight of Sn, based on a total metal weight. When the metal powder includes at least two metal components, the metal powder may be formed using an alloy of the at least two metal components. When the metal powder is obtained using the alloy, the metal powder may not substantially include an organic material.

The solder paste 120 may include a mixture in which conductive metal powder is mixed with a liquid flux. The flux may be prepared by mixing respective components, such as a solvent, a rosin, a thixotropic agent, and an activator.

Specifically, the solvent may include an organic solvent having a boiling point of about 180° C. or higher, such as diethylene glycol monohexyl ether, diethylene glycol monobutyl ether, diethylene glycol monobutyl ether acetate, tetraethylene glycol, 2-ethyl-1,3-hexanediol, and α-terpineol. In addition, the rosin may include a gum rosin, a hydrogenated rosin, a polymerized rosin, and an ester rosin. In addition, the thixotropic agent may include hydrogenated castor oil, fatty acid amide, natural fat, synthetic fat, N,N′-ethylenebis-12-hydroxystearylamide, 12-hydroxystearic acid, 1,2,3,4-dibenzylidene-D-sorbitol, and derivatives thereof. Furthermore, the activator may include a hydrohalic acid amine salt. However, the solvent, the rosin, the thixotropic agent, and the activator are not limited to the above-described examples.

A mounted amount of the solder paste 120 may be appropriately selected by a person skilled in the art considering a viscosity of the solder paste 120, a size of a bump pad 132, and a size of the core material 110 for reverse reflow, which is to be in the solder paste 120.

The core material 110 for reverse reflow and the solder paste 120 may be on the bump pad 132 of a semiconductor device 130. The semiconductor device 130 may include a first substrate 134 on which the bump pad 132 is arranged, and semiconductor elements (not shown) formed on the first substrate 134.

The first substrate 134 may include an active surface on which semiconductor elements are arranged and an inactive surface opposite to the active surface.

The first substrate 134 may include a semiconductor substrate, specifically, a silicon (Si) substrate. In addition, the first substrate 134 may include a semiconductor element, such as germanium (Ge); or a compound semiconductor, such as silicon carbide (SiC), gallium arsenide (GaAs), indium arsenide (InAs), and indium phosphide (InP).

The first substrate 134 may have a silicon-on-insulator (SOI) structure. For example, the first substrate 134 may include a buried oxide layer (BOX) layer. In some embodiments, the first substrate 134 may include a conductive region (e.g., a doped well or a doped structure). In addition, the first substrate 134 may have various isolation structures, such as a shallow trench isolation (STI) structure.

Various semiconductor elements may be provided on the active surface of the first substrate 134. The semiconductor elements may include a memory device, a core circuit element, a peripheral circuit element, a logic circuit element, or a control circuit element. The memory device may include a volatile semiconductor memory device (e.g., dynamic random access memory (DRAM) and static RAM (SRAM)); and a non-volatile memory device (e.g., flash memory, phase-change RAM (PRAM), resistive RAM (RRAM), ferroelectric RAM (FRAM), magnetic RAM (MRAM), erasable programmable read-only memory (EPROM), electrically erasable PROM (EEPROM), and flash EEPROM.

In addition, a system large-scale integration (LSI) device, an image sensor, a micro-electro-mechanical systems (MEMS) device, an active element, and a passive element may be provided on the active surface of the first substrate 134.

Furthermore, a wiring layer may be provided on the semiconductor elements on the active surface of the first substrate 134. The wiring layer may include a wiring pattern and an insulating layer. In addition, the wiring pattern may be electrically connected to the bump pad 132, which is an electrode terminal.

In other embodiments, the first substrate 134 may include a printed circuit board (PCB).

In some embodiments, the semiconductor device 130 may further include an encapsulant configured to encapsulate the semiconductor elements. The encapsulant may include, for example, an epoxy molding compound (EMC).

The pin 100 including the core material 110 for reverse reflow and the solder paste 120 may be coupled to a metal socket 212 of a module device 210. The module device 210 may include a second substrate 214 and the metal socket 212 formed on a top surface of the second substrate 214.

The second substrate 214 may be a PCB. For example, the second substrate 214 may include a rigid PCB, a flexible PCB, a tape substrate, or a rigid-flexible PCB. In other embodiments, the second substrate 214 may include the same semiconductor substrate as the first substrate 134.

When the second substrate 214 includes a PCB, the second substrate 214 may include a first resin layer and a second resin layer, which are respectively on a top surface and a bottom surface of a body included in the PCB. Each of the first resin layer and the second resin layer may have a multilayered structure. A signal layer, a ground layer, or a power layer may be between the multilayered structures and connected to the wiring pattern. In addition, the wiring pattern may be electrically connected to the metal socket 212.

The first resin layer and the second resin layer may include, for example, an epoxy resin, a urethane resin, a polyimide resin, an acryl resin, a polyolefin resin, or the like.

The metal socket 212 may include a conductive socket. More specifically, the metal socket 212 may include, for example, a copper (Cu) socket, a nickel (Ni) socket, or a nickel-plated aluminum (Al) socket, without being limited thereto.

The core material 110 for reverse reflow and the solder paste 120 will be examined again. The pin 100 may be at a constant height between the bump pad 132 and the metal socket 212. To form the solder layer surrounding the core material 110 for reverse reflow, the solder paste 120 may be reflowed.

When a temperature of the solder paste 120 is increased, a material included in the solder paste 120 may be melted, and thus, a surface of the core material 110 for reverse reflow may be coated with the molten material. Specifically, the solder paste 120 may be melted and move along a sidewall of the core material 110 for reverse reflow. As a result, the solder paste 120 may cover an entire surface of the core material 110 for reverse reflow.

In some embodiments, even when the solder paste 120 is located below the core material 110 for reverse reflow, the molten solder paste 120 may move upward along the surface of the core material 110 for reverse reflow against the direction of gravity. Because a viscosity of the molten solder paste 120 is considerably reduced, the core material 110 for reverse reflow may move closer to the first substrate 134 than when first located on the solder paste 120 that is not melted.

Although not limited by any specific theory, it may be inferred that the solder paste 120 moves upward against gravity due to the movement of the core material 110 for reverse reflow, the surface tension of the surface of the core material 110 for reverse reflow, and the affinity between the second metal layer 115 forming the surface of the core material 110 for reverse reflow and the solder paste 120.

Accordingly, the pin 100 including the core material 110 for reverse reflow and the solder paste 120 may be formed between the bump pad 132 and the metal socket 212.

The manufacture of a typical semiconductor package of a pin-grid-array type may involve first forming a pillar by taking very high process cost and manufacturing time such that a plurality of pins, which are coupled to a metal socket, are formed on a substrate. In addition, a material included in the pillar may be manufactured in a desired shape while satisfying both corrosion resistance and oxidation resistance. That is, the formation of the pin by using the pillar may have a problem in that manufacturing efficiency and productivity are low.

To solve the above-described problem, according to an embodiment, by using the core material 110 for reverse reflow and the solder paste 120 as the pin 100, all of corrosion resistance, oxidation resistance, and high signal transmission characteristics may be satisfied due to material characteristics of the second metal layer (refer to 115 in FIG. 1) that forms an outermost layer of the core material 110 for reverse reflow. Therefore, process cost and manufacturing time may be saved, and thus, ultimately, the manufacturing efficiency and productivity of the semiconductor package 10 may be increased.

In addition, according to an embodiment, the semiconductor package 10 of the pin-grid-array type having a relatively high precision and an excellent bonding strength may be economically provided by using the core material 110 for reverse reflow and the solder paste 120 as the pin 100.

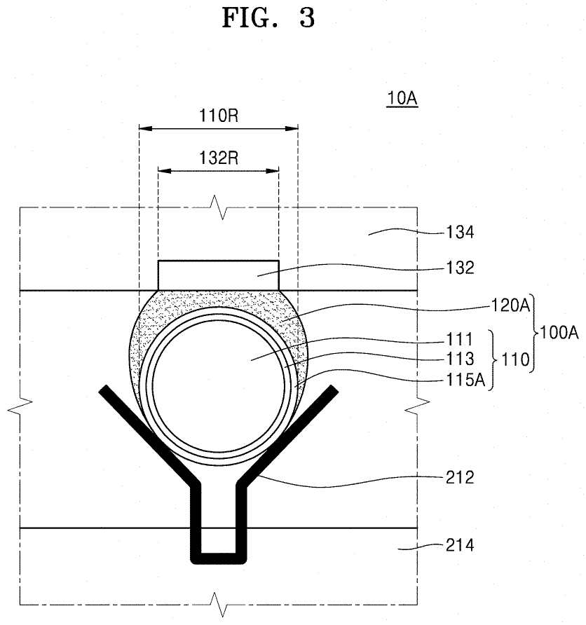

FIG. 3 is a partial enlarged view of region CC of FIG. 2, according to an embodiment.

Referring to FIG. 3, a core material 110 for reverse reflow and solder paste 120A formed only to a side surface of the core material 110 for reverse reflow may be used as a pin 100A, and the pin 100A may be coupled to a metal socket 212.

The core 111 and a first metal layer 113 of the core material 110 for reverse reflow may be the same as those described above with reference to FIG. 1. Moreover, a second metal layer 115A may form an alloy with the solder paste 120A during the formation of a solder layer. FIG. 3 illustrates a semiconductor package 10A including the pin 100A in which a portion of the second metal layer 115A is exposed from the solder paste 120A.

In other words, the portion of the second metal layer 115A may be exposed from the solder paste 120A. By controlling reflow process conditions, the solder layer may not be formed at a lower end (as shown in FIG. 3) of the core material 110 for reverse reflow but may be formed only on the side surface of the core material 110 for reverse reflow. Because the second metal layer 115A that is exposed has high oxidation resistance and excellent conductivity, stability may be ensured during a signal transmission process.

In some embodiments, the second metal layer 115A may form an alloy with the solder paste 120A to a partial thickness thereof. In a portion of the second metal layer 115A, which forms the alloy with the solder paste 120A, the concentration of a component included in the second metal layer 115A may be gradually reduced in a direction away from a surface of the core 111.

Alternatively, the first metal layer 113 may partially or entirely form the intermetallic compound with the solder paste 120A to form an interface layer. Alternatively, the intermetallic compound may include a component of the core 111. In particular, when the first metal layer 113 entirely forms the intermetallic compound with the solder paste 120A, the first metal layer 113 may not be present but the interface layer may be directly present on the surface of the core 111.

Here, the intermetallic compound may be, for example, at least one selected from the group consisting of (Ni,Cu)₃Sn₄, (Cu,Ni)₆Sn₅, and Ni₃Sn₄, but another intermetallic compound may be formed according to materials included in the core 111, the first metal layer 113, the second metal layer 115A, and the solder paste 120A. An intermetallic compound of a component derived from the first metal layer 113 and a component derived from the solder paste 120A may be in the interface layer. Alternatively, an alloy of a component derived from the second metal layer 115A and a component derived from the solder paste 120A may be in the interface layer.

By mixing the solder paste 120A with the second metal layer 115A at a side surface of the core material 110 for reverse reflow, wetting may improve more than when the second metal layer 115A is absent.

A first diameter 132R of the bump pad 132 may be less than or substantially equal to a second diameter 110R of the core material 110 for reverse reflow. That is, a top surface of the bump pad 132 may entirely overlap the core material 110 for reverse reflow.

The metal socket 212 may be in direct contact with the second metal layer 115A of the core material 110 for reverse reflow. That is, the metal socket 212 may not be in contact with the solder paste 120A. Because a material included in the second metal layer 115A has high signal transmission characteristics, a signal transmission process may be performed rapidly.

As described below, even when the second metal layer 115A is exposed from the solder paste 120A in the pin 100A, because a ball shear strength of the pin 100A is higher than a ball shear strength of a typical pin formed using a pillar, there may be no problem in attaching and detaching the pin 100A to and from the metal socket 212.

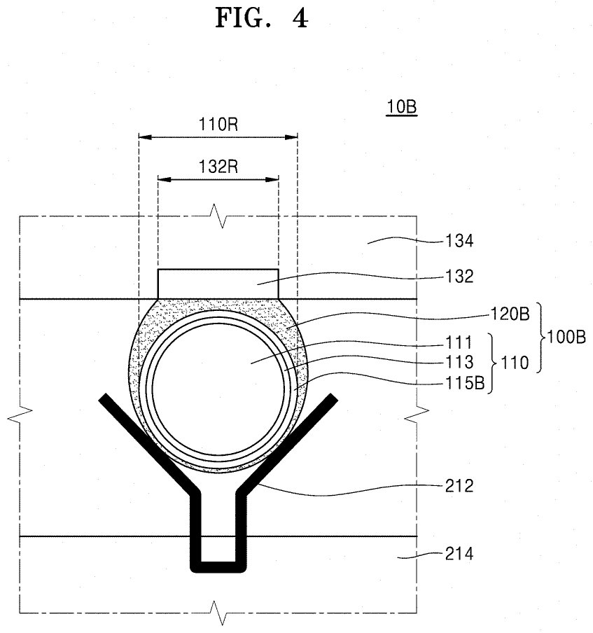

FIG. 4 is a partial enlarged view of region CC of FIG. 2, according to an embodiment.

Referring to FIG. 4, a core material 110 for reverse reflow and solder paste 120B formed on a whole surface of the core material 110 for reverse reflow may be used as a pin 100B, and the pin 100B may be coupled to a metal socket 212.

The core 111 and a first metal layer 113 of the core material 110 for reverse reflow may be the same as those described above with reference to FIG. 1. Moreover, a second metal layer 115B may form an alloy with the solder paste 120B during the formation of a solder layer. FIG. 4 illustrates a semiconductor package 10B including the pin 100B in which the second metal layer 115B is entirely surrounded by the solder paste 120B.

In some embodiments, the second metal layer 115B may form an alloy with the solder paste 120B to a partial thickness thereof. Because the second metal layer 115B forms the alloy with the solder paste 120B, the concentration of a component included in the second metal layer 115B may be gradually reduced in a direction away from a surface of the core 111.

Because the second metal layer 115B has a small thickness of about 0.1 μm to about 0.3 μm, the second metal layer 115B may be entirely melted by heating and form the alloy with the solder paste 120B. Although not shown, the second metal layer 115B may entirely form an alloy and/or an intermetallic compound with the solder paste 120B, without being limited thereto.

When the second metal layer 115B entirely forms the intermetallic compound with the solder paste 120B as described above, the intermetallic compound may be applied to a high-power device.

Alternatively, the first metal layer 113 may partially or entirely form the intermetallic compound with the solder paste 120B to form an interface layer. Alternatively, the intermetallic compound may include a component of the core 111. In particular, when the first metal layer 113 entirely forms the intermetallic compound with the solder paste 120B, the first metal layer 113 may not be present but the interface layer may be directly present on the surface of the core 111.

Here, the intermetallic compound may be, for example, at least one selected from the group consisting of (Ni,Cu)₃Sn₄, (Cu,Ni)₆Sn₅, and Ni₃Sn₄, but another intermetallic compound may be formed according to materials included in the core 111, the first metal layer 113, the second metal layer 115B, and the solder paste 120B. An intermetallic compound of a component derived from the first metal layer 113 and a component derived from the solder paste 120B may be in the interface layer. Alternatively, an alloy of a component derived from the second metal layer 115B and a component derived from the solder paste 120B may be in the interface layer.

By mixing the solder paste 120 with the second metal layer 115B over the whole surface of the core material 110 for reverse reflow, wetting may improve more than when the second metal layer 115B is absent.

A first diameter 132R of the bump pad 132 may be less than or substantially equal to a second diameter 110R of the core material 110 for reverse reflow. That is, a top surface of the bump pad 132 may entirely overlap the core material 110 for reverse reflow.

The metal socket 212 may be in direct contact with the solder paste 120B. That is, the metal socket 212 may not be in direct contact with the core material 110 for reverse reflow.

As described below, even when the second metal layer 115B is entirely surrounded by the solder paste 120B in the pin 100B, because a ball shear strength of the pin 100B is higher than a ball shear strength of a typical pin formed using a pillar, there may be no problem in attaching and detaching the pin 100B to and from the metal socket 212.

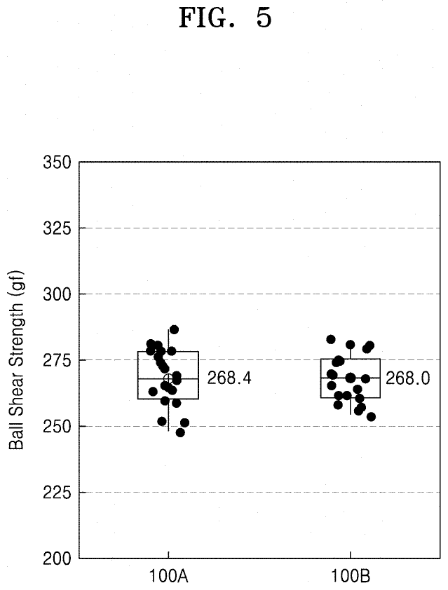

FIG. 5 is a graph showing the strength of a pin in a semiconductor package according to an embodiment.

FIG. 5 shows the ball shear strength of a pin 100A in which a portion of a second metal layer is exposed from solder paste and the ball shear strength of a pin 100B in which a second metal layer is entirely surrounded by solder paste.

When a pin that is physically connected to a metal socket is formed using a typical solder ball, the pin may be deformed due to a low ball shear strength thereof To prevent the deformation of the pin, the pin may have to satisfy a ball shear strength of about 150 gf or more.

As the result of measurements in the present experiment, the pin 100A according to an embodiment had an average ball shear strength of about 268.4 gf, and the pin 100B according to another embodiment had an average ball shear strength of about 268.0 gf.

That is, it was confirmed that the pins 100A and 100B used in the present experiment had the average ball shear strengths of about 180% of a reference strength of about 150 gf. Because the average ball shear strengths described above do not have any problem in attaching and detaching the pins 100A and 1006 to the metal socket, the pins 100A and 100B may be applied to a semiconductor package of a pin-grid-array type.

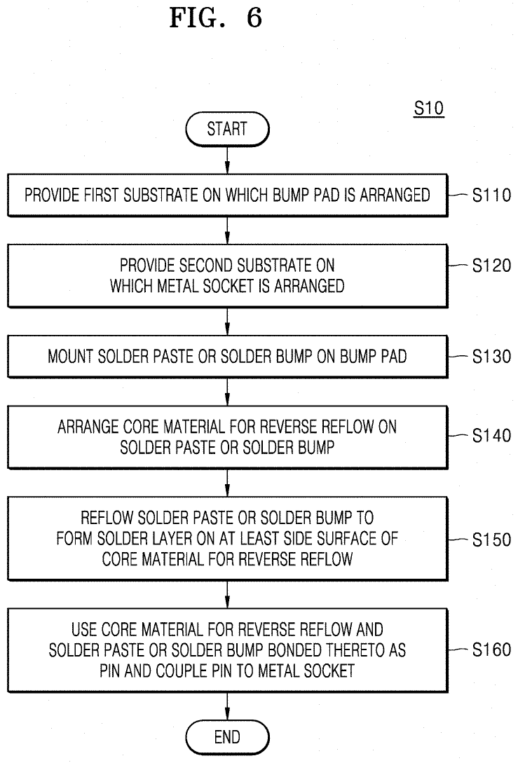

FIG. 6 is a flowchart of a method S10 of manufacturing a semiconductor package, according to an embodiment.

The method S10 of manufacturing the semiconductor package, according to the embodiment, may include a process sequence described below. When some embodiments may be embodied otherwise, respective process operations described herein may be performed otherwise. For example, two process operations described in a sequential order may be performed substantially at the same time or in reverse order.

Referring to FIG. 6, the method S10 of manufacturing the semiconductor package may include a first operation S110 of providing a first substrate on which a bump pad is arranged, a second operation S120 of providing a second substrate on which a metal socket is arranged, a third operation S130 of mounting solder paste or a solder bump on the bump pad, a fourth operation S140 of arranging a core material for reverse reflow on the solder paste or the solder bump, a fifth operation S150 of reflowing the solder paste or the solder bump to form a solder layer on at least a side surface of the core material for reverse reflow, and a sixth operation S160 of using the core material for reverse reflow and the solder paste or the solder bump bonded thereto as a pin and coupling the pin to the metal socket.

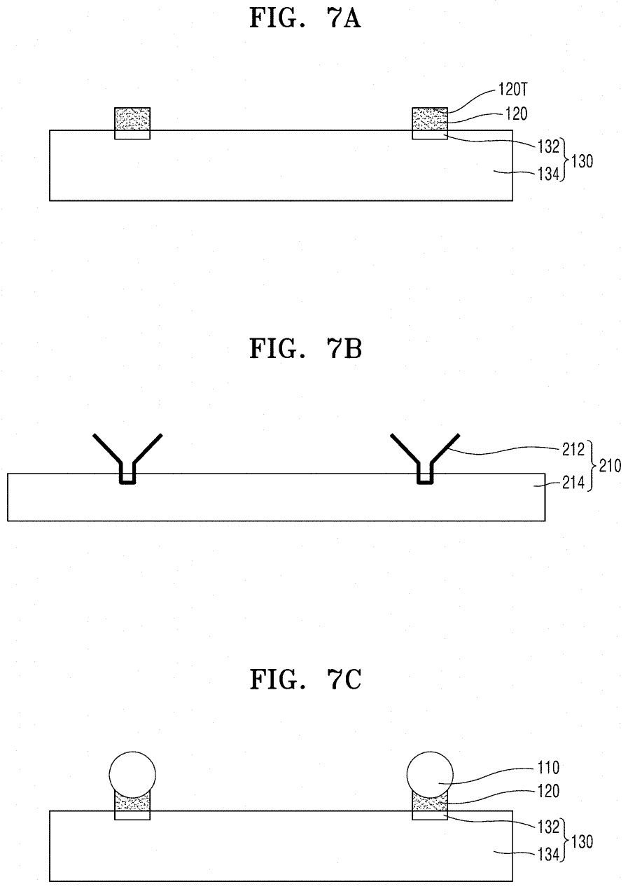

Technical characteristics of each of first to sixth operations S110 to S160 will be described below in detail with reference to FIGS. 7A to 7E.

FIGS. 7A to 7E are cross-sectional views of a process sequence of a method of manufacturing a semiconductor package, according to an embodiment.

Referring to FIG. 7A, a semiconductor device 130 having a bump pad 132 may be provided, and solder paste 120 may be mounted on the bump pad 132.

The semiconductor device 130 may include a first substrate 134, the bump pad 132 formed on a surface of the first substrate 134, and semiconductor elements on the first substrate 134.

The solder paste 120 may include a mixture in which conductive metal powder is mixed with a liquid flux. A top surface 120T of the solder paste 120 may be planar. Also, the solder paste 120 may be mounted on the bump pad 132 such that a width of the solder paste 120 is substantially equal to a width of the bump pad 132.

Referring to FIG. 7B, a module device 210 having a metal socket 212 may be provided.

The module device 210 may include a second substrate 214 and the metal socket 212 formed on a top surface of the second substrate 214. A central portion of the metal socket 212 may be formed in a concave Y shape so that a pin (refer to 100 in FIG. 7D) may be detachably attached to the central portion thereof.

The metal socket 212 may include a conductive socket. The metal socket 212 may include, for example, a copper (Cu) socket, a nickel (Ni) socket, or a nickel-plated aluminum (Al) socket, without being limited thereto.

Referring to FIG. 7C, a core material 110 for reverse reflow may be on the top surface 120T of the solder paste 120.

Referring to FIG. 1 together, in the core material 110 for reverse reflow, for example, a core 111 may have a diameter of about 21 μm to about 500 μm, a first metal layer 113 may have a thickness of about 1 μm to about 5 μm, and a second metal layer 115 may have a thickness of about 0.01 μm to about 0.3 μm. However, the diameter of the core material 110 for reverse reflow is not limited thereto.

Due to the weight of the core material 110 for reverse reflow, a part of the core material 110 for reverse reflow may be immersed in the solder paste 120.

Referring to FIG. 7D, to form a solder layer on at least a side surface of the core material 110 for reverse reflow, a reflow process may be performed on the solder paste 120.

When a temperature of the solder paste 120 is increased, the solder paste 120 may be melted, and thus, a surface of the core material 110 for reverse reflow may be completely coated with the solder paste 120. Specifically, the solder paste 120 may be melted and move along a sidewall of the core material 110 for reverse reflow. As a result, the solder paste 120 may cover at least a side surface of the core material 110 for reverse reflow.

Even when the solder paste 120 is located below the core material 110 for reverse reflow, the molten solder paste 120 may move upward along the surface of the core material 110 for reverse reflow against the direction of gravity. In this case, because a viscosity of the molten solder paste 120 is considerably reduced, the core material 110 for reverse reflow may move closer to the first substrate 134 than when first located on the solder paste 120 that is not melted. It may be inferred that the solder paste 120 moves upward against gravity due to the movement of the core material 110 for reverse reflow, the surface tension of the surface of the core material 110 for reverse reflow, and the affinity between the second metal layer (refer to 115 in FIG. 1) forming the surface of the core material 110 for reverse reflow and the solder paste 120.

The reflow process may be performed at a temperature of about 200° C. to about 300° C. Also, the reflow process may be performed for about 20 seconds to about 100 seconds.

Accordingly, the pin 100 using the core material 110 for reverse reflow and the solder paste 120 may be formed in plural on the first substrate 134.

Referring to FIG. 7E, the semiconductor device 130 may be on the module device 210 with the pin 100 and the metal socket 212 therebetween.

Here, the semiconductor device 130 and the module device 210 may be a predetermined distance apart from each other. That is, before a coupling process is performed, the semiconductor device 130 may be aligned with the module device 210 such that each pin 100 is precisely coupled to the metal socket 212 corresponding thereto. In some embodiments, the semiconductor device 130 may not only be coupled (or attached) to the module device 210 but also isolated (or detached) from the module device 210.

Referring back to FIG. 2, a process of forming a semiconductor package 10 of a pin-grid-array type by coupling the pin 100 to the metal socket 212 may be performed.

According to an embodiment, by using the core material 110 for reverse reflow and the solder paste 120 as the pin 100, all of corrosion resistance, oxidation resistance, and high signal transmission characteristics may be satisfied due to material characteristics of the second metal layer (refer to 115 in FIG. 1) that forms an outermost layer of the core material 110 for reverse reflow. Therefore, process cost and manufacturing time may be saved, and thus, ultimately, the manufacturing efficiency and productivity of the semiconductor package 10 may be increased.

Furthermore, according to an embodiment, the semiconductor package 10 of the pin-grid-array type, which has a high precision and an excellent bonding strength, may be economically provided by using the core material 110 for reverse reflow and the solder paste 120 as the pin 100.

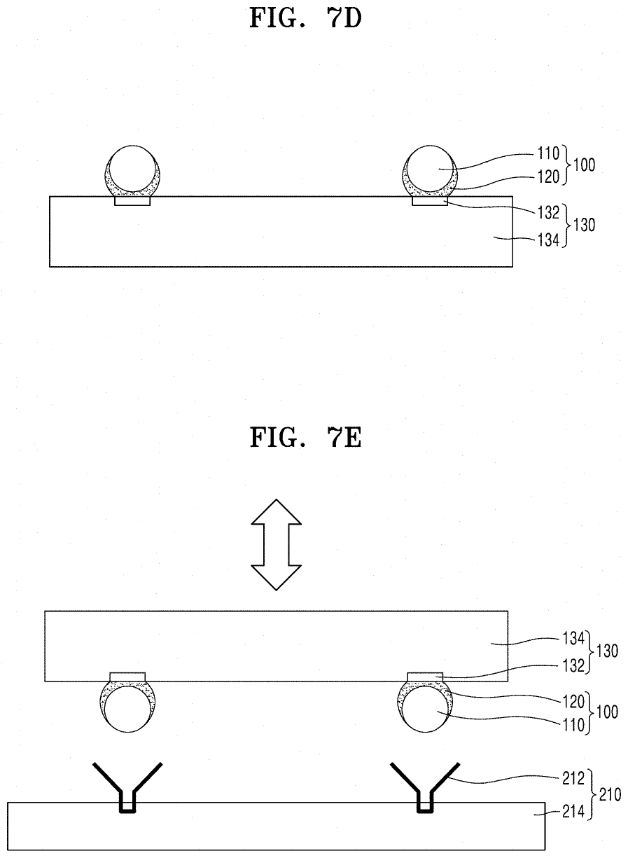

FIG. 8 is a plan view of a memory module 1000 including a semiconductor package, according to an embodiment.

Referring to FIG. 8, the memory module 1000 may include a PCB 1100 and a plurality of semiconductor packages 1200.

Each of the semiconductor packages 1200 may correspond to or include the semiconductor package 10 described above with reference to FIG. 2.

The memory module 1000 may be a single in-line memory module (SIMM) in which the plurality of semiconductor packages 1200 are mounted on only one surface of the PCB 1100 or a dual in-line memory module (DIMM) in which the plurality of semiconductor packages 1200 are mounted on both surfaces of the PCB 1100. In addition, the memory module 1000 may be a fully buffered DIMM (FBDIMM) having an advanced memory buffer (AMB) configured to respectively provide signals from the outside to the plurality of semiconductor packages 1200.

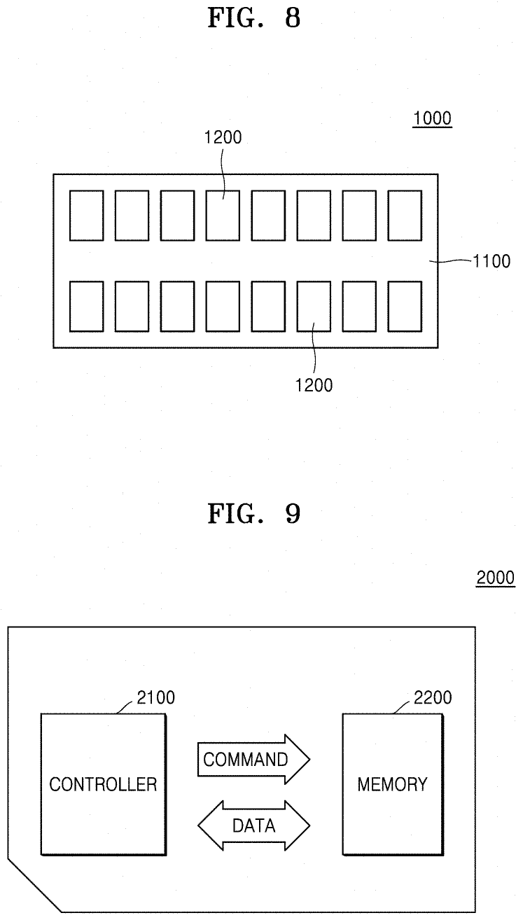

FIG. 9 is a schematic view of a memory card 2000 including a semiconductor package, according to an embodiment.

Referring to FIG. 9, a controller 2100 and a memory 2200 may be in the memory card 2000 to exchange electric signals.

The memory 2200 may correspond to or include the semiconductor package 10 described above with reference to FIG. 2.

The memory card 2000 may constitute various kinds of cards, for example, various memory cards, such as a memory stick card, a smart media (SM) card, a secure digital (SD) card, a mini-SD card, and a multimedia card.

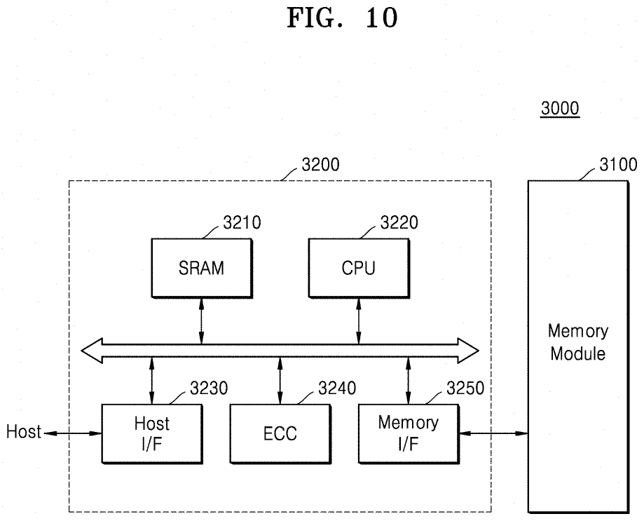

FIG. 10 is a block diagram of a memory device 3000 including a semiconductor package, according to an embodiment.

Referring to FIG. 10, the memory device 3000 may include a memory module 3100 and a memory controller 3200.

The memory module 3100 may correspond to or include the semiconductor package 10 described above with reference to FIG. 2. The memory device 3000 may include a memory controller 3200 configured to control data exchange between a host Host and the memory module 3100.

The memory controller 3200 may include a central processing unit (CPU) 3220 configured to control all operations of a memory card. In addition, the memory controller 3200 may include SRAM, which is used as an operating memory of the CPU 3220. Furthermore, the memory controller 3200 may further include a host interface (I/F) 3230 and a memory IF 3250.

The host IF 3230 may include a data exchange protocol between the memory device 3000 and the host Host. The memory IF 3250 may connect the memory controller 3200 to the memory module 3100. Furthermore, the memory controller 3200 may further include an error correction code (ECC) 3240. The ECC 3240 may detect and correct an error in data read from the memory module 3100.

Although not shown, the memory device 3000 may further include a ROM device configured to store code data required for interfacing with the host Host. The memory device 3000 may be implemented as a solid-state drive (SSD) that may replace a hard disk of a computer system.

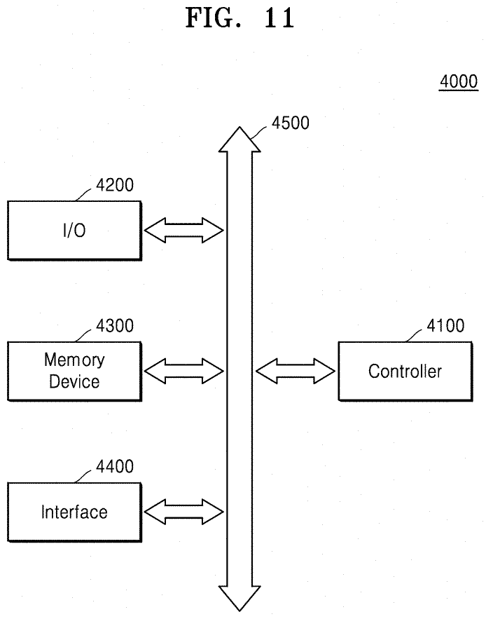

FIG. 11 is a block diagram of an electronic system 400 including a semiconductor package, according to an embodiment.

Referring to FIG. 11, the electronic system 4000 may include a controller 4100, an input/output (I/O) device 4200, a memory device 4300, an interface 4400, and a bus 4500.

The controller 4100, the I/O device 4200, the memory device 4300, and/or the interface 4400 may be combined with each other via the bus 4500. The bus 4500 may correspond to a path through which data is moved.

The controller 4100 may include at least one of a microprocessor, a digital signal processor, a microcontroller, and local elements capable of performing similar functions thereto.

The I/O device 4200 may include a keypad, a keyboard, a touch pad, or a display device.

The memory device 4300 may store data and/or commands. The memory device 4300 may correspond to or include the semiconductor package 10 described above with reference to FIG. 2.

The interface 4400 may transmit data to a communication network or receive data from the communication network. The interface 4400 may be a wired type or a wireless type. For example, the interface 4400 may include an antenna or a wired/wireless transceiver.

Although not shown, the electronic system 4000 may further include a high-speed DRAM device and/or an SRAM device as an operating memory device for improving operations of the controller 4100.

The electronic system 4000 may be applied to all electronic products capable of transmitting and receiving information in a wireless environment, for example, personal digital assistants (PDAs), portable computers, tablets, wireless phones, mobile phones, digital music players, and memory cards.

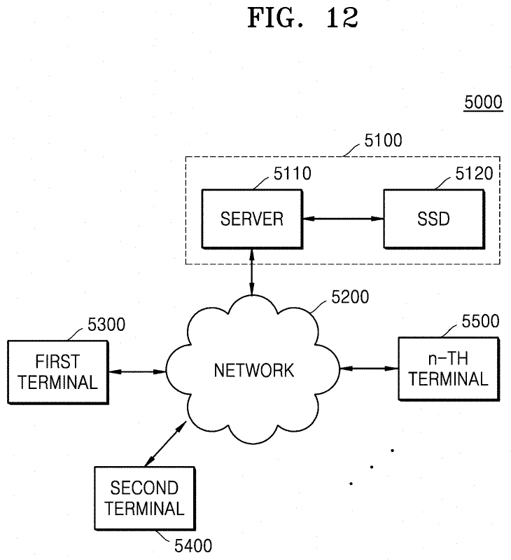

FIG. 12 is a block diagram of a network 5200 for a server system 5100 including a semiconductor package 10, according to an embodiment.

Referring to FIG. 12, a network system 5000 may include the server system 5100 and a plurality of terminals (e.g., first, second, and n-th terminals 5300, 5400, and 5500), which are connected through the network 5200.

The server system 5100 may include a server 5110 configured to process requests received from the first, second, and n-th terminals 5300, 5400, and 5500 connected to the network 5200 and an electronic device 5120 configured to store data corresponding to the requests received from the first, second, and n-th terminals 5300, 5400, and 5500.

The electronic device 5120 may correspond to or include the semiconductor package 10 described above with reference to FIG. 2. The electronic device 5120 may be, for example, an SSD.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A semiconductor package of a pin-grid-array type, the semiconductor package comprising:
a bump pad on a first substrate;
a metal socket on a second substrate;
a core material for reverse reflow on the bump pad; and
solder paste or a solder bump forming a solder layer on the core material for reverse reflow, the solder paste or the solder bump being in contact with the bump pad,
wherein the core material for reverse reflow and the solder paste or the solder bump bonded to the core material for reverse reflow are used as a pin and detachably attached to the metal socket,
a first diameter of the bump pad is less than or equal to a second diameter of the core material for reverse reflow, and
the core material for reverse reflow comprises:
a core;
a first metal layer directly coated on the core, the first metal layer comprising nickel (Ni) or cobalt (Co); and
a second metal layer directly coated on the first metal layer, the second metal layer comprising gold (Au) or platinum (Pt).

2. The semiconductor package of claim 1, wherein, when the solder layer is mixed with the second metal layer at a side surface of the core material for reverse reflow, wetting is further increased as compared to a case in which the second metal layer is absent.

3. The semiconductor package of claim 2, wherein
the solder layer is formed to the side surface of the core material for reverse reflow, and
the metal socket is detachably attached to the pin to directly contact the second metal layer and not to contact the solder layer.

4. The semiconductor package of claim 2, wherein
the solder layer is formed on a whole surface of the core material for reverse reflow, and
the metal socket is detachably attached to the pin to directly contact the solder layer.

5. The semiconductor package of claim 2, wherein a thickness of the solder layer is gradually reduced in a direction away from the first substrate.

6. The semiconductor package of claim 1, wherein
the core has a diameter of about 21 μm to about 500 μm, and
the second metal layer has a thickness of about 0.01 μm to 0.3 μm.

7. A method of manufacturing a semiconductor package of a pin-grid-array type, the method comprising:
providing a first substrate on which a bump pad is arranged;
providing a second substrate on which a metal socket is arranged;
mounting solder paste or a solder bump on the bump pad;
arranging a core material for reverse reflow on the solder paste or the solder bump;
reflowing the solder paste or the solder bump to form a solder layer on at least a side surface of the core material for reverse reflow; and
using the core material for reverse reflow and the solder paste or the solder bump bonded to the core material for reverse reflow as a pin and coupling the pin to the metal socket,
wherein the core material for reverse reflow comprises:
a core;
a first metal layer directly coated on the core, the first metal layer comprising nickel (Ni) or cobalt (Co); and
a second metal layer directly coated on the first metal layer, the second metal layer comprising gold (Au) or platinum (Pt).

8. The method of claim 7, wherein a first diameter of the bump pad is less than or equal to a second diameter of the core material for reverse reflow.

9. The method of claim 7, wherein
the solder layer is formed to the side surface of the core material for reverse reflow, and
the metal socket is coupled to the pin to directly contact the second metal layer and not to contact the solder layer.

10. The method of claim 7, wherein
the solder layer is formed on a whole surface of the core material for reverse reflow, and
the metal socket is coupled to the pin to directly contact the solder layer.
